(19) United States
(12) Patent Application Publication
(10) Pub. No.: US 2025/0301681 A1
(43) Pub. Date: Sep. 25, 2025

(54) SEMICONDUCTOR DEVICE AND METHOD OF FORMING THE SAME

(71) Applicant: HON HAI PRECISION INDUSTRY CO., LTD., New Taipei City (TW)

(72) Inventors: Jheng-Sheng YOU, New Taipei City (TW); Hung-Yu CHEN, New Taipei City (TW); Wen-Yuan HSIEH, New Taipei City (TW)

(21) Appl. No.: 18/648,491

(22) Filed: Apr. 29, 2024

(30) Foreign Application Priority Data
Mar. 20, 2024 (TW) 113110379

(51) Int. Cl. H01L 29/66; H01L 29/40; H01L 29/417; H01L 29/778

(52) U.S. Cl. CPC H10D 30/015; H10D 30/475; H10D 64/111; H10D 64/251

(57) ABSTRACT

A method of forming a semiconductor device includes forming a channel layer and a barrier layer on a substrate; forming a gate structure on the barrier layer, conformally forming a first dielectric layer on the barrier layer and the gate structure; forming a second dielectric layer spaced apart from the gate structure on the first dielectric layer; forming an ohmic contact metal layer on the first dielectric layer and the second dielectric layer, in which the ohmic contact metal layer contacts the barrier layer through a first opening and a second opening of the first dielectric layer; and etching the ohmic contact metal layer. A source electrode filled in the first opening, a drain electrode filled in the second opening, and a field plate disposed between the source electrode and the drain electrode and partially covering the second dielectric layer are formed. A semiconductor device is also disclosed.

### RELATED APPLICATIONS

This application claims priority to Taiwanese Application Serial Number 113110379, filed Mar. 20, 2024, which is herein incorporated by reference.

### BACKGROUND

### Field of Invention

The present disclosure relates to a semiconductor device and method of forming the same.

### Description of Related Art

Power semiconductor devices have been rapidly developed and are widely utilized in various fields such as wireless communications, electronic devices, electric vehicles, etc. However, the high power devices require high breakdown voltage, high electron mobility, great thermal stability, etc. Therefore, there is a need to provide an enhanced semiconductor device and method of forming the same.

### SUMMARY

According to some embodiments of the disclosure, a method of forming a semiconductor device includes sequentially forming a channel layer and a barrier layer on a substrate; forming a gate structure on the barrier layer; conformally forming a first dielectric layer on the barrier layer and the gate structure; forming a second dielectric layer on the first dielectric layer, wherein the second dielectric layer is spaced apart from the gate structure; forming a first opening and a second opening in the first dielectric layer, the second dielectric layer and the gate structure are disposed between the first opening and the second opening; forming an ohmic contact metal layer on the first dielectric layer and the second dielectric layer, wherein the ohmic contact metal layer contacts the barrier layer through the first opening and the second opening; and etching the ohmic contact metal layer to form a source electrode filled in the first opening, a drain electrode filled in the second opening, and a field plate disposed between the source electrode and the drain electrode and partially covering the second dielectric layer.

According to some embodiments of the disclosure, a semiconductor device includes a channel layer disposed on a substrate; a barrier layer disposed on the channel layer; a gate structure disposed on the barrier layer; a first dielectric layer conformally disposed on the barrier layer and the gate structure; a source electrode and a drain electrode disposed at opposite sides of the gate structure and penetrating the first dielectric layer to contact the barrier layer; a second dielectric layer disposed on the first dielectric layer, and a field plate disposed between the source electrode and the drain electrode and partially covering the second dielectric layer. The second dielectric layer is disposed between the gate structure and the drain electrode. The source electrode, the drain electrode, and the field plate are made of the same ohmic contact metal.

According to some embodiments of the disclosure, a semiconductor device includes a channel layer disposed on a substrate; a barrier layer disposed on the channel layer; a gate structure disposed on the barrier layer; a first dielectric layer conformally disposed on the barrier layer and the gate structure; a source electrode and a drain electrode disposed at opposite sides of the gate structure and penetrating the first dielectric layer to contact the barrier layer; a second dielectric layer disposed on the first dielectric layer, an etch stop layer disposed between the second dielectric layer and the first dielectric layer, and a field plate disposed between the source electrode and the drain electrode and partially covering the second dielectric layer. The second dielectric layer is disposed between the gate structure and the drain electrode. The etch stop layer with the second dielectric layer thereon and the gate structure are spaced apart, and the etch stop layer with the second dielectric layer thereon and the drain electrode are spaced apart.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 to FIG. 5 are cross-sectional views of different stages of a method of forming a semiconductor device according to some embodiments of the disclosure.

FIG. 6 and FIG. 7 are cross-sectional views of the semiconductor device according to some other embodiments of the disclosure.

### DESCRIPTION OF THE EMBODIMENTS

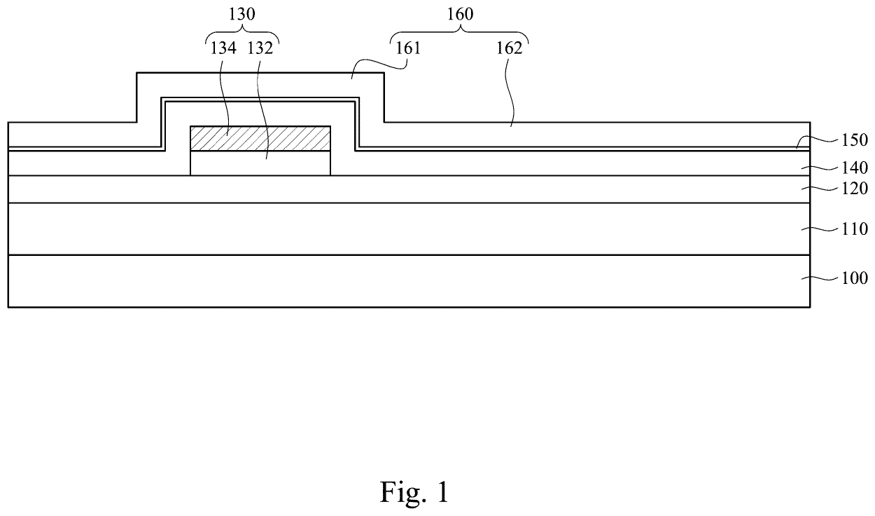

Reference is made to FIG. 1 to FIG. 5, which are cross-sectional views of different stages of a method of forming a semiconductor device according to some embodiments of the disclosure. As shown in FIG. 1, the method of forming a semiconductor device begins at forming a channel layer 110 on a substrate 100, and forming a barrier layer 120 on the channel layer 110. The substrate 100 can be a semiconductor substrate such as a Si substrate or a SiC substrate. The substrate 100 can include semiconductor components, compounds and/or alloy. In some embodiments, even though not illustrated in the drawing, the substrate 100 further includes active components (such as diodes), passive components (such as resistors, capacitors), conductive wires, the likes, or the combinations.

The channel layer 110 can provide a channel between source and drain. The barrier layer 120 is benefit to form a two-dimensional electron gas (2DEG) carrier path within the channel layer 110, in which the 2DEG carrier path has high concentration, high electron mobility, and lower resistance. In some embodiments, the material of the channel layer 110 includes epitaxial GaN. In some embodiments, the material of the barrier layer 120 includes AlGaN.

A gate structure 130 is formed on the barrier layer 120 to control the carrier passing or not of the channel layer 110. In some embodiments, the gate structure 130 includes a patterned doping layer 132 and a gate metal layer 134 on the doping layer 132. The doping layer 132 can be doped with N-type dopants such as dopants of group IV including C, Si, Ge, Sn, etc. or can be doped with P-type dopants such as dopants of group II including Be, Mg, Ca, Sr, etc. For example, the doping layer 132 can be GaN doped with P-type dopants. The material of the gate metal layer 134 can include suitable metal materials, such as Cu, Ag, W, Ni, and TiN, etc.

The step illustrated in FIG. 1 further includes forming a first dielectric layer 140 continuously and conformally extending on the barrier layer 120 and the gate structure 130. The first dielectric layer 140 is directly in contact with the barrier layer 120 and the gate structure 130. In some embodiments, the first dielectric layer 140 covers the barrier layer 120 and continuously covers the top surface and the side surface of the gate structure 130. In some embodiments, the material of the first dielectric layer 140 includes SiO₂, Si₃N₄, SiON, or the combinations thereof.

Then, an etch stop layer 150 is conformally formed on the first dielectric layer 140. That is, the etch stop layer 150 is also continuously and conformally extending on the barrier layer 120 and the gate structure 130. In some embodiments, the material of the etch stop layer 150 includes AlN, Al₂O₃, SiN, or the combinations thereof.

Then, a second dielectric material layer 160 is conformally formed on the etch stop layer 150. That is, the second dielectric material layer 160 is continuously extending on the etch stop layer 150. The material of the etch stop layer 150 is different from the materials of the first dielectric layer 140 and the second dielectric material layer 160. The material of the first dielectric layer 140 can be the same as or different from the material of the second dielectric material layer 160. In some embodiments, the material of the second dielectric material layer 160 includes SiO₂, Si₃N₄, SiON, or the combinations thereof.

The gate structure 130 is protruded from the barrier layer 120, and the first dielectric layer 140, the etch stop layer 150, and the second dielectric material layer 160 are conformally formed on the barrier layer 120 and the gate structure 130. Thus the second dielectric material layer 160 has a first portion 161 on the gate structure 130 and a second portion 162 on the barrier layer 120, and a height of the first portion 161 is higher than a height of the second portion 162.

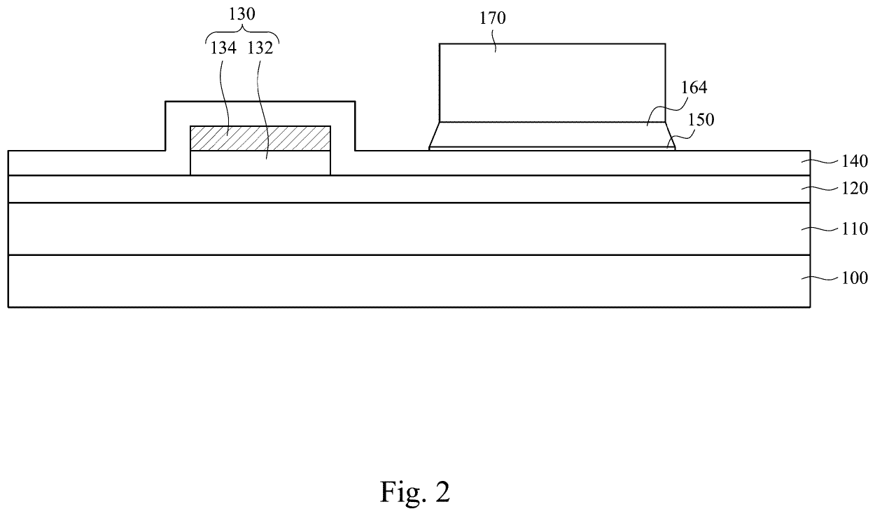

As shown in FIG. 2, a patterned mask 170 is formed on the second portion 162 of the second dielectric material layer 160, and an etching process using the patterned mask 170 as a mask is performed to remove portions of the second dielectric material layer 160 and the etch stop layer 150 that are not protected by the patterned mask 170. The material of the etch stop layer 150 is different from the materials of the first dielectric layer 140 and the second dielectric material layer 160, so that the first dielectric layer 140 would not be over etched during removing the unprotected second dielectric material layer 160, and the first dielectric layer 140 remains covering the gate structure 130 and the barrier layer 120. The step in FIG. 2 further includes performing a photoresist stripping process and a cleaning process to remove the patterned mask 170 and the remaining etch stop layer 150, if exists.

In some embodiments, the etching process can be a dry etching process or a wet etching process. The remained portion of the second dielectric material layer 160 after the etching process is referred as a second dielectric layer 164, and the second dielectric layer 164 is spaced apart from the gate structure 130. The sidewall of the second dielectric layer 164 can be vertical or inclined. Namely, in some embodiments, the second dielectric layer 164 has a trapezoid cross-section after the etching process. The second dielectric layer 164 includes the second portion 162 of FIG. 1 which is disposed on the barrier layer 120 and has the lower height.

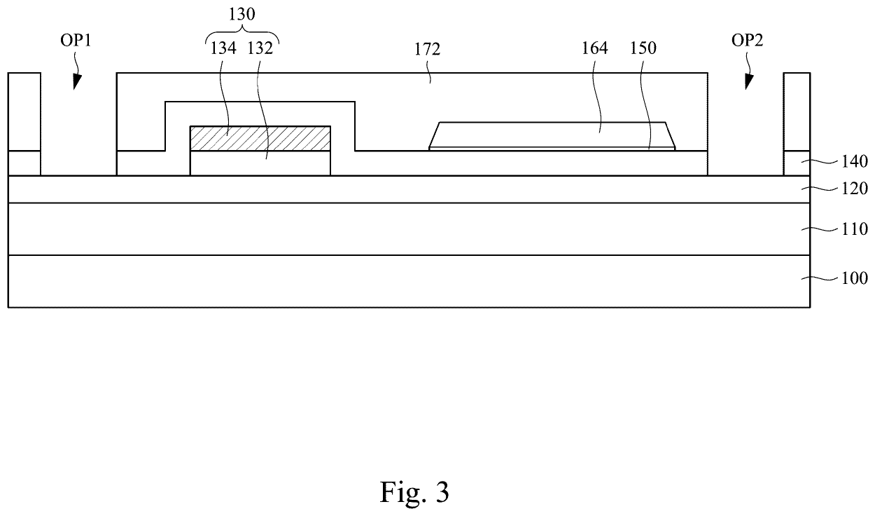

Then, as shown in FIG. 3, an additional patterned photoresist 172 is formed on the structure of FIG. 2, in which the patterned photoresist 172 covers the gate structure 130 and the second dielectric layer 164. The patterned photoresist 172 includes a first opening OP1 and a second opening OP2 disposed at opposite sides of the gate structure 130 and the second dielectric layer 164. That is, the gate structure 130 and the second dielectric layer 164 are disposed between the first opening OP1 and the second opening OP2.

Sequentially, an etching process using the patterned photoresist 172 as a mask is performed to remove portions of the first dielectric layer 140 that are not protected by the patterned photoresist 172. The patterns of the first opening OP1 and the second opening OP2 are transferred to the first dielectric layer 140. Namely, after the etching process is performed, the first opening OP1 and the second opening OP2 are also defined in the first dielectric layer 140, and the barrier layer 120 is exposed through the first opening OP1 and the second opening OP2.

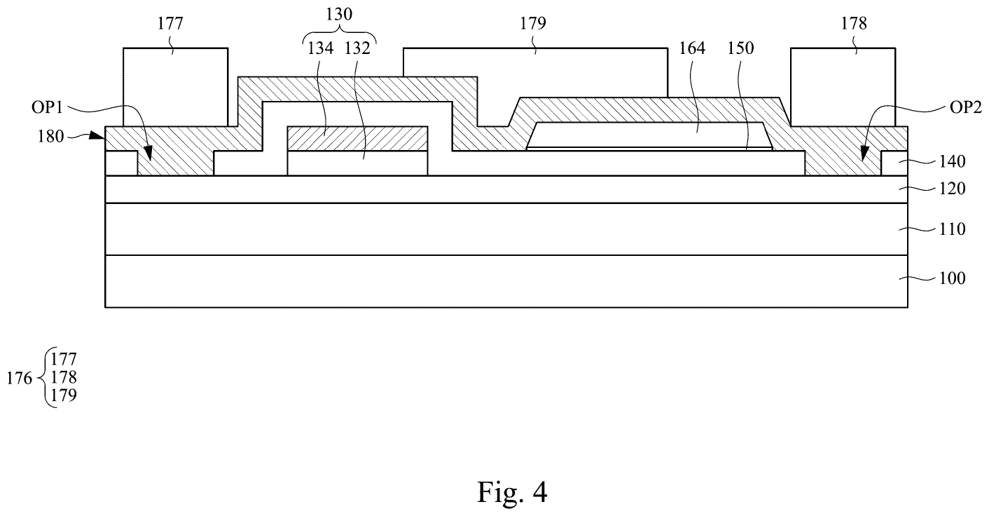

As shown in FIG. 4, an ohmic contact metal layer 180 is deposited on the structure of FIG. 3. The ohmic contact metal layer 180 continuously covers the first dielectric layer 140 and is connected to the barrier layer 120 via the first opening OP1 and the second opening OP2. In some embodiments, the material of the ohmic contact metal layer 180 includes Ti/AITi/Au, Pt/Au, or the like.

Then, an additional patterned photoresist 176 is formed on the ohmic contact metal layer 180. The patterns of the patterned photoresist 176 would decide the layout of the following formed field plate, source electrode, and drain electrode. For example, in some embodiments, the patterned photoresist 176 includes a first portion 177 that covers the first opening OP1 to define a source electrode, a second portion 178 that covers the second opening OP2 to define a drain electrode, and a third portion 179 that covers a portion of the gate structure 130 and a portion of the first dielectric 140 to define a field plate. The first portion 177, the second portion 178, and the third portion 179 are separated from each other.

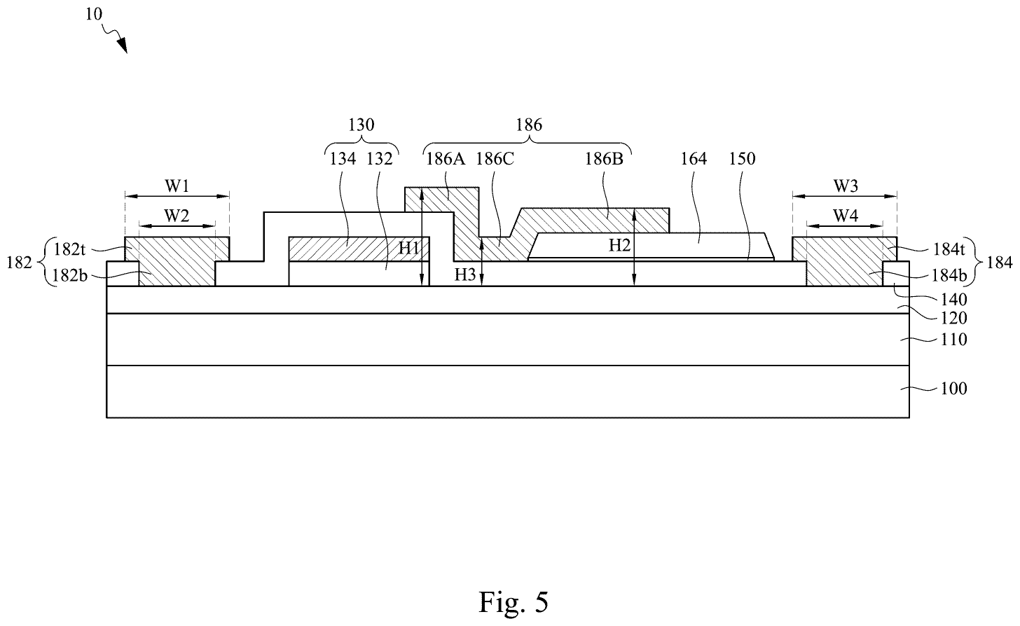

An etching process using the patterned photoresist 176 as a mask is performed to remove portions of the ohmic contact metal layer 180 that are not protected by the patterned photoresist 176. Then, the patterned photoresist 176 is removed, and a semiconductor device 10 as shown in FIG. 5 is provided.

Referring to FIG. 5, the semiconductor device 10 includes the substrate 100, the channel layer 110 on the substrate 100, and the barrier layer 120 on the channel layer 110. The 2DEG can be formed between the channel layer 110 and the barrier layer 120. The semiconductor device 10 further includes the gate structure 130 disposed on the barrier layer 120, a source electrode 182 disposed at a side of the gate structure 130 and filled in the first opening OP1, and a drain electrode 184 disposed at another side of the gate structure 130 and filled in the second opening OP2.

The composition of the gate structure 130 is different from the composition of the source electrode 182 and the drain electrode 184. More particularly, the gate structure 130 includes the doping layer 132 and the gate metal layer 134 on the doping layer 132. The material of the source electrode 182 and the drain electrode 184 is ohmic contact metal. In some embodiments, the cross-sectional shape of the gate structure 130 is different from the cross-sectional shape of the source electrode 182 and the drain electrode 184. For example, the cross-sectional shape of the gate structure 130 is a rectangle. The cross-sectional shape of the source electrode 182 includes a top section 182t and a bottom section 182b connecting to the top section 182t. The width W1 of the top section 182t is greater than the width W2 of the bottom section 182b, and the top section 182t and the bottom section 182b are integratedly formed in one piece without an interface therebetween. The cross-sectional shape of the drain electrode 184 includes a top section 184t and a bottom section 184b connecting to the top section 184t. The width W3 of the top section 184t is greater than the width W4 of the bottom section 184b, and the top section 184t and the bottom section 184b are integratedly formed as a single piece without an interface therebetween.

The semiconductor device 10 includes the first dielectric layer 140. The first dielectric layer 140 partially covers the barrier layer 120 and continuously covers the top surface and the side surface of the gate structure 130. In some embodiments, the first dielectric layer 140 is disposed surrounding the bottom section 182b of the source electrode 182 and is disposed between the top section 182t of the source electrode 182 and the barrier layer 120. The first dielectric layer 140 is disposed surrounding the bottom section 184b of the drain electrode 184 and is disposed between the top section 184t of the drain electrode 184 and the barrier layer 120.

The semiconductor device 10 includes the etch stop layer 150 disposed on the first dielectric layer 140. The etch stop layer 150 is disposed between the gate structure 130 and the drain electrode 184. The semiconductor device 10 includes the second dielectric layer 164 on the etch stop layer 150. The etch stop layer 150 with the second dielectric layer 164 thereon are spaced apart from the gate structure 130 by a distance. The etch stop layer 150 with the second dielectric layer 164 thereon are spaced apart from the drain electrode 184 by a distance.

The semiconductor device 10 includes a field plate 186. The field plate 186 partially covers the gate structure 130 and continuously extends from the gate structure 130 to the second dielectric layer 164. The field plate 186 partially covers the second dielectric layer 164. The field plate 186, the source electrode 182, and the drain electrode 184 are made from the same ohmic contact metal layer 180 (as shown in FIG. 4) and are defined by the same etching process. Therefore, the field plate 186, the source electrode 182, and the drain electrode 184 are formed simultaneously and are made of the same ohmic contact metal material.

In some embodiments, a height difference is present between the second dielectric layer 164 and the gate structure 130. Therefore, the field plate 186 formed thereon has sections at different levels accordingly. For example, the field plate 186 has a first section 186A on the gate structure 130, a second section 186B on the second dielectric layer 164, and a third section 186C interconnecting the first section 186A and the second section 186B. The height H1 of the first section 186A is different from the height H2 of the second section 186B, and the height H1 of the first section 186A and the height H2 of the second section 186B are both higher than the height H3 of the third section 186C, in which the heights H1, H2, H3 are measured from the top surface of the barrier layer 120 to the top surface of the corresponding section.

In some embodiments, the first section 186A of the field plate 186 is at an end farther from the drain electrode 184, and the second section 186B of the field plate 186 is at an end closer to the drain electrode 184. The second section 186B is disposed between the first section 186A and the drain electrode 184.

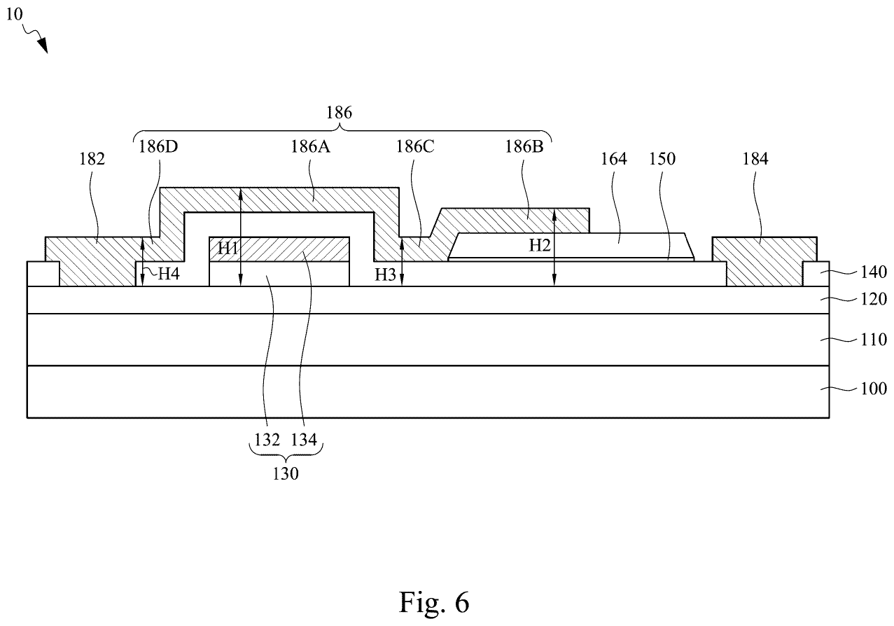

Reference is made to FIG. 6, which is a cross-sectional view of the semiconductor device according to some other embodiments of the disclosure. According to the designs of the pattern photoresist 176 of FIG. 4, the field plate 186 may also have different designs. For example, in some embodiments, the field plate 186 is connected to the source electrode 182. That is, the field plate 186 further includes a fourth section 186D, and the fourth section 186D interconnects the first section 186A and the source electrode 182. In some embodiments, the fourth section 186D of the field plate 186 is at an end farther from the drain electrode 184, and the second section 186B of the field plate 186 is at an end closer to the drain electrode 184. The height H4 of the fourth section 186D is substantially equal to the height H3 of the third section 186C and is lower than the height H2 of the second section 186B. Namely, the top surface and the side surface of the gate structure 130 are covered by the field plate 186, and the gate structure 130 and the field plate 186 are spaced apart by the first dielectric layer 140.

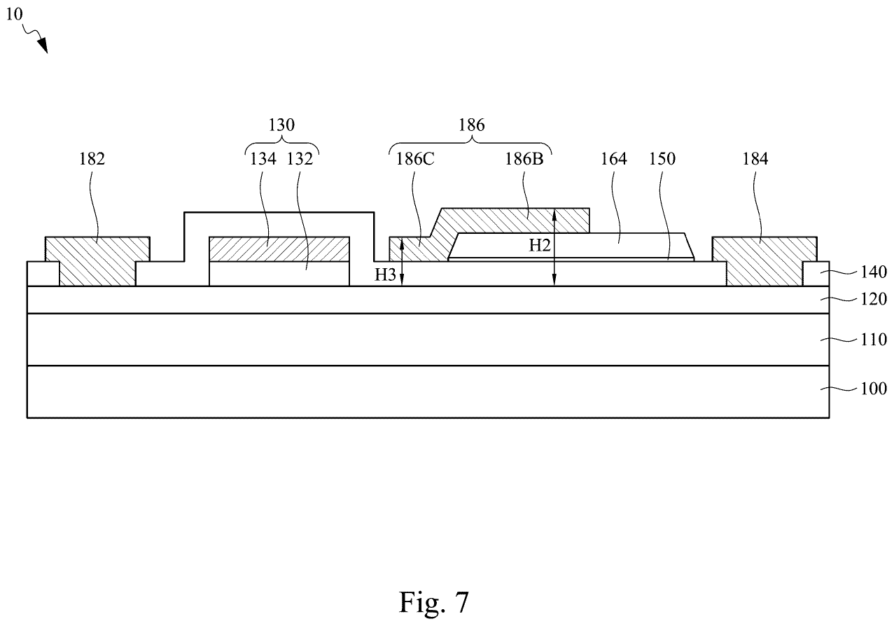

Reference is made to FIG. 7, which is a cross-sectional view of the semiconductor device according to some other embodiments of the disclosure. According to the designs of the pattern photoresist 176 of FIG. 4, the field plate 186 may also have different designs. For example, in some embodiments, the field plate 186 does not cover the gate structure 130. Namely, the field plate 186 includes the second section 186B on the second dielectric layer 164 and the third section 186C between the gate structure 130 and the second dielectric layer 164. The height H2 of the second section 186B is higher than the height H3 of the third section 186C.

According to above embodiments, the field plate 186 of the semiconductor device 10 includes sections at two or more levels. Therefore, the single field plate 186 can provide function as a multilayer field plate, including precisely adjusting the ratio of the gate-source charge (Q_{gs}) and the gate-drain charge (Q_{gd}). Additionally, the source electrode 182 and the drain electrode 184 of the field plate 186 are defined by the same etching process, so that the mask number can be reduced and the fabricating processes can be simplified. Further, the field plate 186 based on the underlying step profile, so that the sections of the field plate 186 have sufficient height differences to significantly increase breakdown voltage.

What is claimed is:

1. A method of forming a semiconductor device comprising:
sequentially forming a channel layer and a barrier layer on a substrate;
forming a gate structure on the barrier layer;
conformally forming a first dielectric layer on the barrier layer and the gate structure;
forming a second dielectric layer on the first dielectric layer, wherein the second dielectric layer is spaced apart from the gate structure;
forming a first opening and a second opening in the first dielectric layer, the second dielectric layer and the gate structure are disposed between the first opening and the second opening;
forming an ohmic contact metal layer on the first dielectric layer and the second dielectric layer, wherein the ohmic contact metal layer contacts the barrier layer through the first opening and the second opening; and
etching the ohmic contact metal layer to form a source electrode filled in the first opening, a drain electrode filled in the second opening, and a field plate disposed between the source electrode and the drain electrode and partially covering the second dielectric layer.

2. The method of claim 1, wherein etching the ohmic contact metal layer is performed using a same patterned photoresist as a mask to form the source electrode, the drain electrode, and the field plate simultaneously.

3. The method of claim 1, wherein forming the second dielectric layer on the first dielectric layer comprises:
forming an etch stop layer on the first dielectric layer;
conformally forming a second dielectric material layer on the etch stop layer; and
etching the second dielectric material layer and the etch stop layer to form the second dielectric layer.

4. A semiconductor device comprising:
a channel layer disposed on a substrate;
a barrier layer disposed on the channel layer;
a gate structure disposed on the barrier layer;
a first dielectric layer conformally disposed on the barrier layer and the gate structure;
a source electrode and a drain electrode disposed at opposite sides of the gate structure and penetrating the first dielectric layer to contact the barrier layer;
a second dielectric layer disposed on the first dielectric layer, wherein the second dielectric layer is disposed between the gate structure and the drain electrode; and
a field plate disposed between the source electrode and the drain electrode and partially covering the second dielectric layer, wherein the source electrode, the drain electrode, and the field plate are made of the same ohmic contact metal.

5. The semiconductor device of claim 4, wherein the field plate comprises a first section partially covering the gate structure, a second section partially covering the second dielectric layer, and a third section interconnecting the first section and the second section, wherein a height of the first section is different from the second section.

6. The semiconductor device of claim 5, wherein the field plate further comprises a fourth section interconnecting the first section and the source electrode, wherein a height of the fourth section is lower than the height of the second section.

7. The semiconductor device of claim 4, wherein the field plate comprises a second section partially covering the second dielectric layer and a third section between the second section and the gate structure, wherein the third section is connected to the second section, and a height of the second section is higher than a height of the third section.

8. The semiconductor device of claim 4, wherein the second dielectric layer and the gate structure are spaced apart, and the second dielectric layer and the drain electrode are spaced apart.

9. A semiconductor device comprising:
a channel layer disposed on a substrate;
a barrier layer disposed on the channel layer;
a gate structure disposed on the barrier layer;
a first dielectric layer conformally disposed on the barrier layer and the gate structure;
a source electrode and a drain electrode disposed at opposite sides of the gate structure and penetrating the first dielectric layer to contact the barrier layer;
a second dielectric layer disposed on the first dielectric layer, wherein the second dielectric layer is disposed between the gate structure and the drain electrode;
an etch stop layer disposed between the second dielectric layer and the first dielectric layer, wherein the etch stop layer with the second dielectric layer thereon and the gate structure are spaced apart, and the etch stop layer with the second dielectric layer thereon and the drain electrode are spaced apart; and
a field plate disposed between the source electrode and the drain electrode and partially covering the second dielectric layer.

10. The semiconductor device of claim 9, wherein the source electrode, the drain electrode, and the field plate are made of the same material.

11. The semiconductor device of claim 9, wherein the gate structure comprises a doping layer and a gate metal layer on the doping layer.

12. The semiconductor device of claim 9, wherein a material of the etch stop layer is different from a material of the first dielectric layer and the second dielectric layer.
